(19) United States
(12) Patent Application Publication
(10) Pub. No.: US 2014/0095825 A1
(43) Pub. Date: Apr. 3, 2014

(54) SEMICONDUCTOR DEVICE AND OPERATING METHOD THEREOF

(71) Applicant: SK hynix Inc., Icheon-si (KR)

(72) Inventors: Young-Suk MOON, Icheon-si (KR); Yong-Kee KWON, Seoul (KR); Hong-Sik KIM, Seongnam-si (KR)

(73) Assignee: SK hynix Inc., Icheon-si (KR)

(21) Appl. No.: 14/012,386

(22) Filed: Aug. 28, 2013

(30) Foreign Application Priority Data
Sep. 28, 2012 (KR) 10-2012-0109164

(51) Int. Cl. G11C 7/10

(52) U.S. Cl. CPC G11C 7/1039
USPC 711/169

(57) ABSTRACT

An operating method of a semiconductor device may comprise determining whether a read request is pending, setting a delay interval in accordance with a density of requests if there is no read request pending; and processing a write request after the delay interval.

### CROSS-REFERENCE TO RELATED APPLICATIONS

The present application claims priority to Korean Patent Application No. 10-2012-0109164, filed on Sep. 28, 2012, in the Korean Intellectual Property Office, which is incorporated herein by reference in its entirety as set forth in full.

### BACKGROUND

1. Technical Field

Embodiments of the present invention generally relate to a semiconductor device and an operating method thereof, and more particularly to a semiconductor device capable of determining a processing order of read and write operations of a semiconductor memory device, and an operating method thereof.

2. Related Art

A semiconductor memory device such as a dynamic random access memory (DRAM) may be controlled by a memory controller. The memory controller may include an arbitration block for determining a processing order of read and write requests from a host.

The memory controller according to a prior art begins to process a write request after delaying a predetermined interval, for example a time interval, when there are no read requests pending.

The memory controller may lower the performance of a system because of the delay interval.

### SUMMARY

Various embodiments are directed to a semiconductor device including a read queue and a write queue for storing read requests and write requests to a semiconductor memory device and capable of determining a processing order of read and write requests and an operating method thereof.

In an embodiment, an operating method of a semiconductor device may comprise determining whether a read request is pending; setting a delay interval in accordance with a density of requests if there is no read request pending; and processing a write request after the delay interval.

In the operating method, setting the delay interval may comprise setting the delay interval as a first interval if the density of requests exceeds a predetermined value.

In the operating method, setting the delay interval may further comprise setting the delay interval as a second interval greater than the first interval if the density of requests does not exceed the predetermined value.

In another embodiment, a semiconductor device may comprise a dispatch block for processing a write request after a delay interval based on a density of requests from a host if there is no read request pending.

In the semiconductor device the dispatch block may determine the delay interval as a first interval if the density of requests exceeds a predetermined threshold value and the dispatch block may determine the delay interval as a second interval greater than the first interval if the density of requests does not exceed the predetermined threshold value.

In another embodiment, a system may comprise a semiconductor memory device; and a memory controller for controlling the memory device, wherein the memory controller may include a read request storage for storing a read request; a write request storage for storing a write request; and a dispatch block for processing the write request after a delay interval based on a density of requests where the write request is processed if the read request storage is empty.

In the system, the dispatch block may determine the delay interval as a first interval if the density of requests exceeds a predetermined threshold value and the dispatch block may determine the delay interval as a second interval greater than the first interval if the density of requests does not exceed the predetermined threshold value.

In another embodiment, a storage medium may store steps executed by a processor wherein the steps may comprise determining whether a read request is pending; setting a delay interval in accordance with a density of requests from a host if there is no read request pending; and processing a write request after the delay interval.

In the storage medium, setting the delay interval may comprise setting the delay interval as a first interval if the density of requests exceeds a predetermined value.

In the storage medium, setting the delay interval may further comprise setting the delay interval as a second interval greater than the first interval if the density of requests does not exceed the predetermined value.

### BRIEF DESCRIPTION OF THE DRAWINGS

FIG. 1 is a block diagram illustrating a semiconductor device in accordance with an embodiment of the present invention.

FIG. 2 is a block diagram illustrating an arbitration block in accordance with an embodiment of the present invention.

FIG. 3 is a flow chart illustrating an operation of the arbitration block in accordance with an embodiment of the present invention.

FIG. 4 is a flow chart illustrating an operation of the request monitoring unit in accordance with an embodiment of the present invention.

FIG. 5 is a graph illustrating performance of a semiconductor device in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey a scope of the present invention to those skilled in the art. Throughout the disclosure, like reference numerals refer to like parts throughout the various figures and embodiments of the present invention.

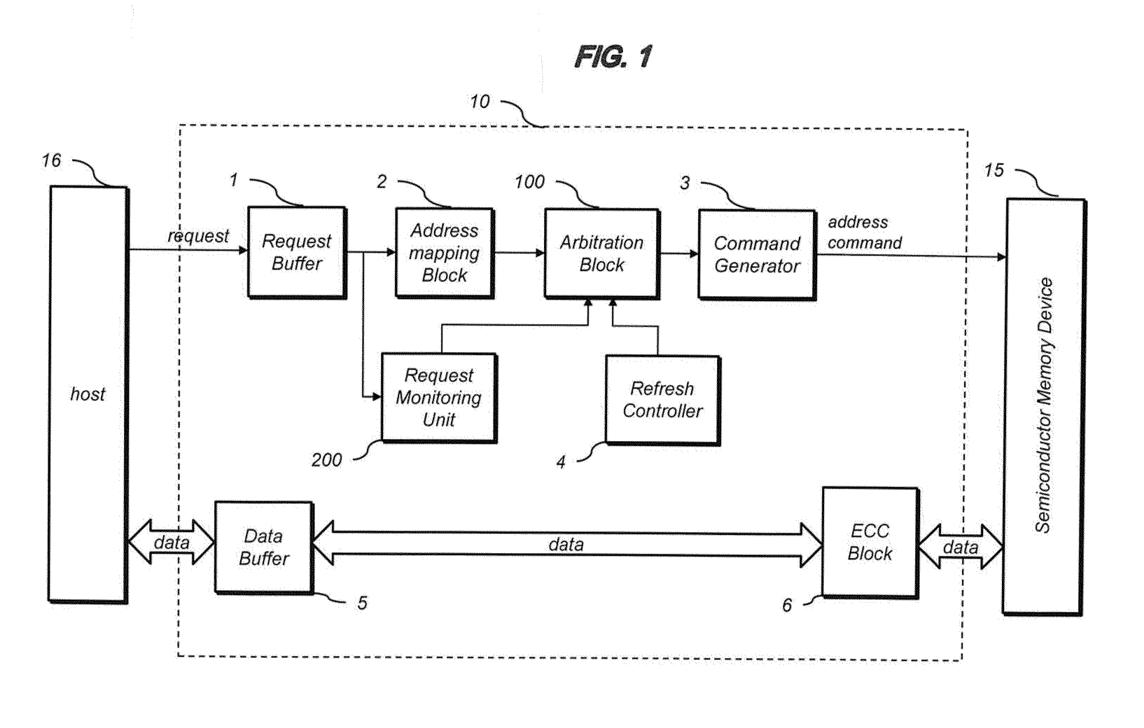

FIG. 1 is a block diagram illustrating a semiconductor device 10 in accordance with an embodiment of the present invention.

The semiconductor device 10 in accordance with embodiments of the present invention may be embodied as a memory controller for controlling a semiconductor memory device 15 or a processor including the memory controller. Therefore a memory controller referenced in the present disclosure may designate a memory controller itself or a processor including the memory controller therein.

The semiconductor device 10 in FIG. 1 may include a request buffer 1, an address mapping block 2, a command generator 3, a refresh controller 4, a data buffer 5, and an error correction code (ECC) block 6. The address mapping block 2 may map a logical address from a host to a physical address of the semiconductor memory device 15. The command generator 3 may generate a command for controlling the semiconductor memory device 15 corresponding to a request. The refresh controller 4 may control refresh operations of a semiconductor memory device 15. The data buffer 5 may temporarily store data to and from the host. The ECC block 6 may detect and/or correct errors in data read from the semiconductor memory device 15. The functions and structures of the request buffer 1, the address mapping block 2, the command generator 3, the refresh controller 4, the data buffer 5, and the ECC block 6 are well known.

The semiconductor device 10 in FIG. 1 may further include an arbitration block 100 for determining a processing order of requests from a host 16. The semiconductor device 10 of FIG. 1 may also include a request monitoring unit 200 for monitoring requests from the host 16.

The request monitoring unit 200 may monitor whether a density of requests from the host 16 exceeds a predetermined threshold value during a predetermined period of time. The density of requests may be based on a number of requests received from the host 16 during the predetermined period of time. In one example the density of requests is the number of read requests that the semiconductor device 10 receives from the host 16 during the predetermined period of time. In other examples, the density of requests is the number of read and write requests that the semiconductor device 10 receives from the host 16 during the predetermined period of time.

The arbitration block 100 may determine a processing order of read and write requests from the host 16. Depending on the density of requests, the arbitration block 100 may further determine whether or not processing for a write request should be delayed when there is no read request pending.

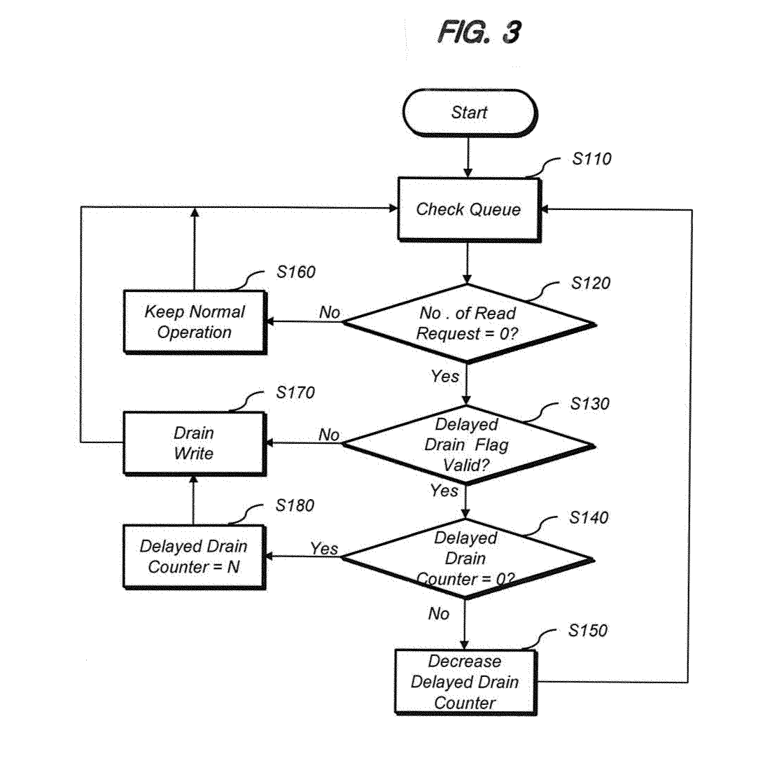

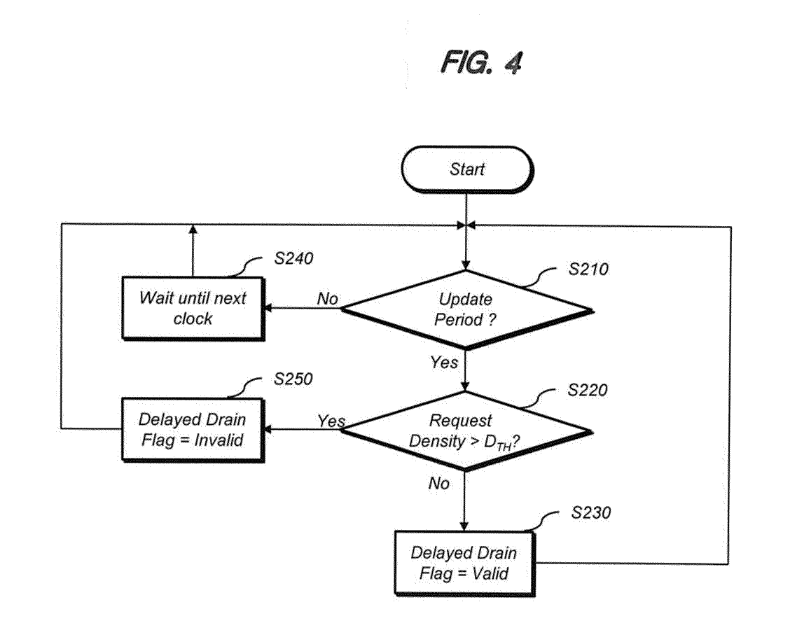

The operations of the arbitration block 100 and request monitoring unit 200 are disclosed in detail with reference to FIG. 3 and FIG. 4.

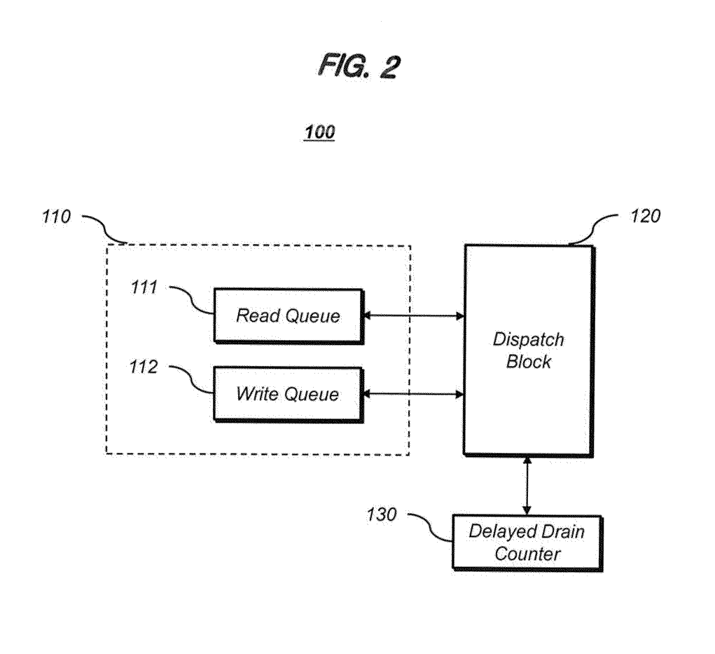

FIG. 2 is a block diagram illustrating an arbitration block 100 in accordance with an embodiment of the present invention.

The arbitration block 100 may comprise a request storage 110, a dispatch block 120, and a delayed drain counter 130. The request storage 110 may store requests from the host 16.

The request storage 110 may include a read request storage 111 for storing read requests and a write request storage 112 for storing write requests. In an embodiment, each of the read request storage 111 and the write request storage 112 may have a queue data structure, but the kind of data structure of the read and write request storages 111, 112 is not limited thereto. In one embodiment, a read request storage 111 may be represented by a read queue 111 and a write request storage 112 may be represented by a write queue 112.

The read queue 111 may store one or more read requests and the write queue 112 may store one or more write requests. Each request may include address information therefor.

The dispatch block 120 may determine the processing order of requests stored in the read queue 111 and the write queue 112. Some operations of the dispatch block 120 will be disclosed in detail with reference to FIG. 3.

The delayed drain counter 130 may set an interval to wait before processing a write request in the write queue 112 when the read queue 111 is empty, i.e., no read requests are pending in the read queue 111. In one example, the delayed drain counter 130 may be initially set to 0. Thus, in one embodiment, a write request is processed without delay when the read queue 111 is empty.

FIG. 3 is a flow chart illustrating an operating method of the arbitration block 100 according to an embodiment of the present invention.

Though it is not shown in the figure, the delayed drain counter 130 may be set to have an initial value.

The dispatch block 120 may check a status of the read queue 111 and the write queue 112 at step S110.

The dispatch block 120 may check whether the read queue 111 is empty at step S120.

If the read queue 111 is not empty, the dispatch block 120 may select a read request or a write request by using known techniques at step S160.

If the read queue 111 is empty (i.e., no read requests are pending), the dispatch block 120 may check whether a delayed drain flag is valid at step S130. The delayed drain flag may be set by the request monitoring unit 200 based on the density of requests received by the semiconductor device 10 in a predetermined period of time.

If the delayed drain flag is not valid, which indicates that the density of requests exceeds a predetermined threshold value DTH, the write request is processed without delaying at step S170.

If the delayed drain flag is valid, the dispatch block 120 may determine whether a predetermined interval is exceeded by checking whether the value of the delayed drain counter 130 is 0 at step S140.

If the value of the delayed drain counter 130 is not 0, the delayed drain counter 130 counts down at step S150 and the process proceeds to the step S110.

If the value of the delayed drain counter 130 is 0, the value of the delayed drain counter is set to the initial value at step S180 and the write request is processed at step S170.

FIG. 4 is a flow chart illustrating an operating method of the request monitoring unit 200 according to an embodiment of the present invention.

The request monitoring unit 200 may update the validity of delayed drain flag by checking the density of requests for a predetermined update period of time, where the density of requests includes read and write requests that the semiconductor device 10 receives. The request monitoring unit 200 may also increment the density of requests each time the semiconductor device 10 receives a read or write request.

The request monitoring unit 200 may check whether the update period of time has passed at step S210.

If the update period of time has not passed, the request monitoring unit 200 waits for another clock cycle at step S240.

If the update period of time has passed, the request monitoring unit 200 may determine whether the density of requests exceeds the predetermined threshold value DTH at step S220.

The delayed drain flag is set to not valid (invalid) if the density of requests exceeds the threshold value at step S250, and the delayed drain flag is set to valid if the density of request does not exceed the threshold value at step S230.

In the embodiment disclosed with reference to FIG. 3 and FIG. 4, if the read queue 112 is empty the arbitration block 100 determines whether processing a write request should be delayed or not considering the delayed drain flag.

In other embodiments, if the read queue 112 is empty the arbitration block 100 may determine that processing a write request may be delayed for a first interval when the delayed drain flag is not valid and processing a write request may be delayed for a second interval greater than the first interval when the delayed drain flag is valid. In this case, the first interval may be set 0 by setting the delayed drain counter to 0, which results in the aforementioned embodiment.

In an example to countdown the first interval and the second interval at the delayed drain counter 130, the initial value thereof may be set differently by considering the delayed drain flag. In other example, the delayed drain counter 130 may include first sub counter and second sub counter which countdown the first interval and the second interval respectively and one of the first sub counter or the second counter may be selected to countdown by the delayed drain flag. Thus in one embodiment the methods disclosed herein, comprise; determining whether a read request is pending, setting a delay interval in accordance with density of requests from a host if there is no read request pending; and processing a write request after the delay interval is exceeded.

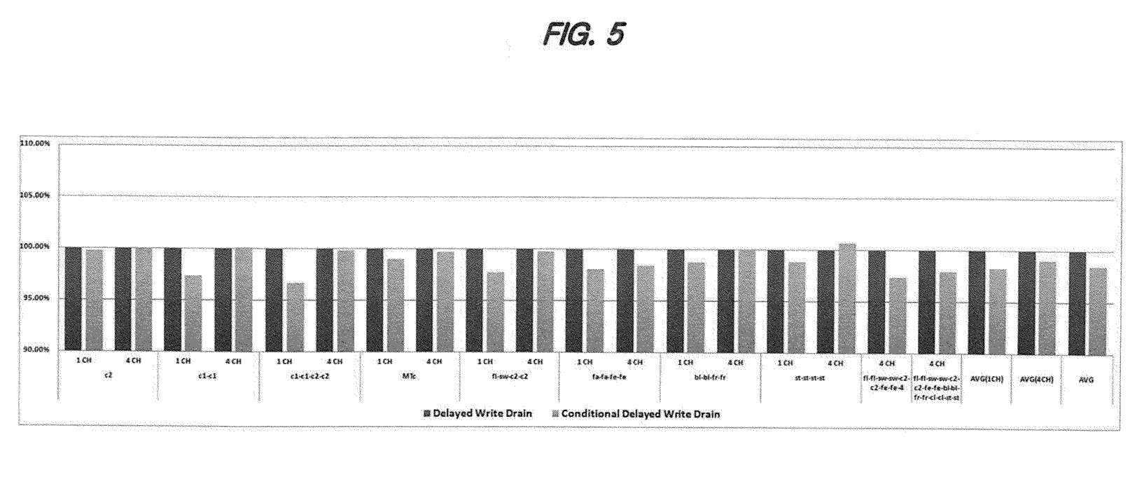

FIG. 5 is a graph illustrating performance of a semiconductor device in accordance with an embodiment of the present invention.

The graph represents a simulation result performed with a USIMM (http://utaharch.blogspto.kr/2012/02/usimm.html) simulator and a PARSEC benchmark.

The vertical axis of the graph represents a read queue latency mean time before data is output from a memory controller (which in one example is embodied by semiconductor device 10), after a request is given to the memory controller.

The graph represents the read queue latency according to an embodiment of the present invention relative to the read queue latency according to a prior art, which is normalized to 100.

The graph shows a performance enhancement by 1.48% in the embodiment of the present invention.

The methods according to the embodiments of the present invention may be recorded in non-transitory computer-readable media including program instructions to implement various operations embodied by a computer. The media may also include, alone or in combination with the program instructions, data files, data structures, and the like. The program instructions recorded on the media may be those specially designed and constructed for the purposes of the embodiments, or they may be of the kind well-known and available to those having skill in the computer software arts. Examples of non-transitory computer-readable media include magnetic media such as hard disks, floppy disks, and magnetic tape; optical media such as CD ROM disks and DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described embodiments of the present invention, or vice versa.

Although various embodiments have been described for illustrative purposes, it will be apparent to those skilled in the art that various changes and modifications may be made without departing from the spirit and scope of the invention as defined in the following claims.

What is claimed is:

1. An operating method of a semiconductor device comprising:
determining whether a read request is pending;
setting a delay interval in accordance with a density of requests if there is no read request pending; and
processing a write request after the delay interval is exceeded.

2. The operating method of claim 1, wherein setting the delay interval comprises setting the delay interval as a first interval if the density of requests exceeds a predetermined value.

3. The operating method of claim 2, wherein setting the delay interval further comprises setting the delay interval as a second interval greater than the first interval if the density of requests does not exceed the predetermined value.

4. The operating method of claim 2, wherein the first interval is 0.

5. The operating method of claim 1, further comprising determining the density of requests.

6. The operating method of claim 5, wherein the determining the density of requests comprises determining number of requests from the host for a predetermined period of time.

7. A semiconductor device comprising:
a dispatch block for processing a write request after a delay interval, where the delay interval is based on a density of requests, and the write request is processed if there is no read request pending.

8. The semiconductor device of claim 7, further comprising:
a read request storage for storing the read request; and
a write request storage for storing the write request.

9. The semiconductor device of claim 7, wherein the dispatch block determines the delay interval as a first interval if the density of requests exceeds a predetermined threshold value and the dispatch block determines the delay interval as a second interval greater than the first interval if the density of requests does not exceed the predetermined threshold value.

10. The semiconductor device of claim 7, wherein the first interval is 0.

11. The semiconductor device of claim 7, further comprising:
a request monitoring unit for determining the density of requests.

12. A system comprising:
a semiconductor memory device; and
a memory controller for controlling the memory device, wherein the memory controller includes
a read request storage for storing a read request;
a write request storage for storing a write request; and
a dispatch block for processing the write request after a delay interval based on a density of requests, where the write request is processed if the read request storage is empty.

13. The system of claim 12, wherein the dispatch block determines the delay interval as a first interval if the density of requests exceeds a predetermined threshold value and the dispatch block determines the delay interval as a second interval greater than the first interval if the density of requests does not exceed the predetermined threshold value.

14. The system of claim 13, wherein the first interval is 0.

15. The system of claim 12, wherein the memory controller further comprises a request monitoring unit for determining the density of requests.

16. A storage medium storing steps executed by a processor, the steps comprising:
determining whether a read request is pending;
setting a delay interval in accordance with a density of requests if there is no read request pending; and
processing a write request after the delay interval.

17. The storage medium of claim 16, wherein setting the delay interval comprises setting the delay interval as a first interval if the density of requests exceeds a predetermined value.

18. The storage medium of claim 17, wherein setting the delay interval further comprises setting the delay interval as a second interval greater than the first interval if the density of requests does not exceed the predetermined value.

19. The storage medium of claim 17, wherein the first interval is 0.

20. The storage medium of claim 16, wherein the steps further comprises determining the density of requests.
